(19) United States
(12) Patent Application Publication
(10) Pub. No.: US 2025/0040380 A1
(43) Pub. Date: Jan. 30, 2025

(54) DISPLAY MODULE AND DISPLAY DEVICE

(71) Applicant: GUANGDONG OPPO MOBILE TELECOMMUNICATIONS CORP., LTD., Dongguan (CN)

(72) Inventor: Changyu LIU, Dongguan (CN)

(73) Assignee: GUANGDONG OPPO MOBILE TELEVOMMUNICATIONS CORP., LTD., Dongguan (CN)

(21) Appl. No.: 18/913,232

(22) Filed: Oct. 11, 2024

Related U.S. Application Data
(63) Continuation of application No. PCT/CN2022/143717, filed on Dec. 30, 2022.

(30) Foreign Application Priority Data
Apr. 11, 2022 (CN) 202210372359.6

(51) Int. Cl. H10K 59/131; H10K 59/35

(52) U.S. Cl. CPC H10K 59/131; H10K 59/353; H10K 59/351

(57) ABSTRACT

A display module, arranged with a first display region and a first fan-out region that are disposed in sequence in a first direction; wherein the first direction is perpendicular to a thickness direction of the display module. The display module comprises: n first data signal lines, each arranged in the first display region; wherein an extension direction of each first data signal line is parallel to the first direction; and n first fan-out lines, connected to the n first data signal lines in a one-to-one correspondence; wherein each first fan-out line is partially disposed in the first display region and partially disposed in the first fan-out region; n is a positive integer.

### CROSS-REFERENCE TO RELATED APPLICATIONS

The present application is a continuation-application of International (PCT) Patent Application No. PCT/CN2022/143717, filed on Dec. 30, 2022, which claims priority of Chinese Patent Application No. 202210372359.6, filed on Apr. 11, 2022, the entire contents of which are hereby incorporated by reference in their entirety.

### TECHNICAL FIELD

The present disclosure relates to the field of display technologies, and in particular to a display module and a display device.

### BACKGROUND

The statements here are only intended to provide background information related to the present disclosure and do not necessarily constitute exemplary technology.

With the continuous development of science and technology, people have increasingly high requirements for the appearance of display devices. Full screens have become popular in the market, and narrowing the bezels of the display screen and increasing the screen-to-body ratio is particularly important. However, the bezel width of current display devices can no longer meet people's needs, and there is an urgent need for a display device with a narrower lower bezel.

### SUMMARY OF THE DISCLOSURE

In the embodiments of the present disclosure, a display module and a display device are provided.

In a first aspect, the present disclosure provides a display module, arranged with a first display region and a first fan-out region that are disposed in sequence in a first direction; wherein the first direction is perpendicular to a thickness direction of the display module; the display module includes:
n first data signal lines, each arranged in the first display region; wherein an extension direction of each first data signal line is parallel to the first direction; and
n first fan-out lines, connected to the n first data signal lines in a one-to-one correspondence; wherein each first fan-out line is partially disposed in the first display region and partially disposed in the first fan-out region; n is a positive integer.

In a second aspect, the present disclosure provides a display device, including the above display module.

Details of one or more embodiments of the present disclosure are set forth in the following drawings and description. Other features, purposes, and advantages of the present disclosure will become apparent from the description, drawings, and claims.

### BRIEF DESCRIPTION OF THE DRAWINGS

In order to more clearly illustrate the technical solutions in the embodiments or exemplary techniques of the present disclosure, the following is a brief description of the drawings required in the description of the embodiments or exemplary techniques. Obviously, the drawings described below are only some embodiments of the present disclosure. For those skilled in the art, other embodiments can be obtained without creative effort based on these drawings.

FIG. 1 is a structural schematic view of a display module according to some embodiments of the present disclosure.

FIG. 2 is a partial structural schematic view of a first pixel circuit according to some embodiments of the present disclosure.

FIG. 3 is a circuit diagram of a first pixel circuit according to some embodiments of the present disclosure.

FIG. 4 is a partial structural schematic view of another first pixel circuit according to some embodiments of the present disclosure.

FIG. 5 is a partial structural schematic view of an arrangement of light-emitting devices according to some embodiments of the present disclosure.

FIG. 6 is a partial structural schematic view of a display module formed by combining the pixel circuits in FIG. 4 with the light-emitting devices in FIG. 5.

FIG. 7 is a structural schematic view of another display module of according to some embodiments of the present disclosure.

FIG. 8 is a local structural schematic view of a first display region and a first fan-out region according to some embodiments of the present disclosure.

FIG. 9 is a local enlarged view of region (a) circumscribed in FIG. 8.

FIG. 10 is a structural schematic view of a first fan-out line.

FIG. 11 is a local enlarged view of region (b) circumscribed in FIG. 8.

FIG. 12 is a cross-sectional schematic view of a first pixel circuit according to some embodiments of the present disclosure.

### DETAILED DESCRIPTION

In order to make the purpose, technical solution, and advantages of the present disclosure clearer and more understandable, the following is a further detailed description of the present disclosure in conjunction with the accompanying drawings and embodiments. It should be understood that the specific embodiments described herein are provided for the sole purpose of explaining the present disclosure and are not intended to limit the present disclosure.

It should be understood that the terms “first,” “second,” etc., as mentioned in the present disclosure, may be intended to describe various elements, but those elements are not limited by these terms. These terms are only intended to distinguish one element from another. For example, without departing from the scope of the present disclosure, a first pixel circuit may be referred to as a second pixel circuit, and similarly, a second pixel circuit may be referred to as a first pixel circuit. Both the first pixel circuit and the second pixel circuit are pixel circuits, but they are not the same pixel circuit.

In addition, the terms “first” and “second” are intended for descriptive purposes only and are not to be understood as indicating or implying relative importance or as implying a specified number of technical features. Accordingly, features limited by “first” or “second” may explicitly or implicitly include at least one of such features. In the description of the present disclosure, the meaning of “multiple” is at least two, such as two, three, etc., unless otherwise expressly and specifically limited. In the description of the present disclosure, the meaning of “some” is at least one, for example one, two, etc., unless otherwise expressly and specifically limited.

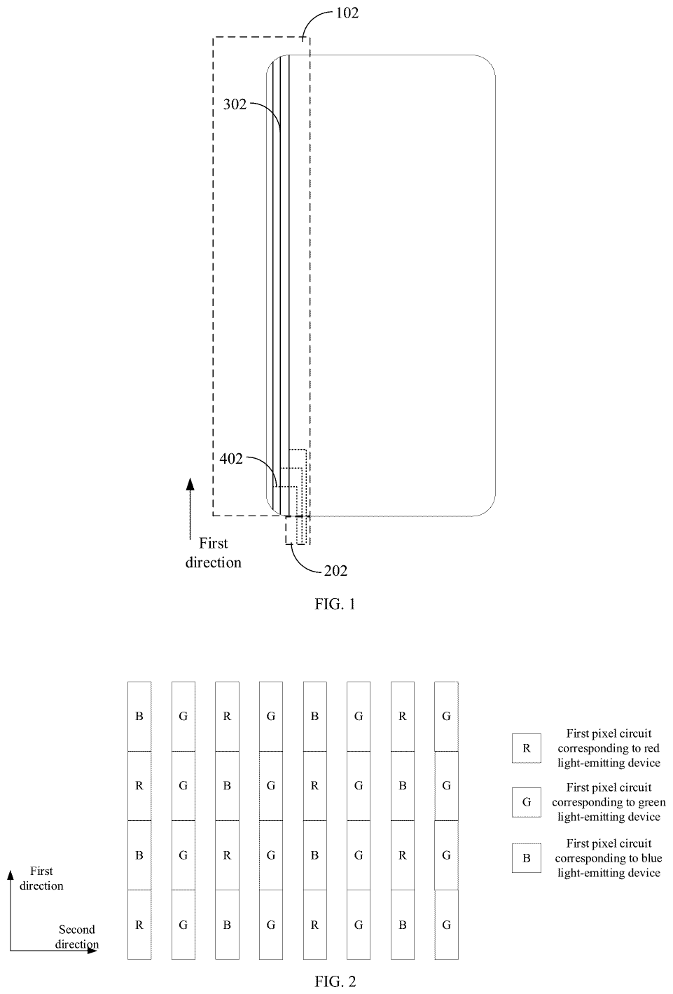

Referring to FIG. 1, FIG. 1 is a structural schematic view of a display module according to some embodiments of the present disclosure. The display module is applied to a display device with narrow bezels. The display device may be a smartphone, tablet, gaming device, augmented reality (AR) device, notebook, desktop computing device, wearable device, etc. For ease of understanding, the following example illustrates the display device as a mobile phone. Referring to FIG. 1, the display module is arranged with a first display region 102 and a first fan-out region 202 arranged in sequence in a first direction, where the first direction is perpendicular to a thickness direction of the display module. The display module has an AA region that can display, and the first display region 102 may be understood as part of the AA region. In addition to the AA region, the display module further includes a fan-out region for setting fan-out lines, and the first fan-out region 202 may be understood as part of the fan-out region.

The display module includes n first data signal lines 302 and n first fan-out lines 402. It should be noted that in order to distinguish the first data signal lines 302 from the first fan-out lines 402, different line types are drawn in the present disclosure to distinguish between them, where the first fan-out lines 402 are marked with dotted lines. However, the above illustration is only intended to distinguish between them in the accompanying drawings, and the first fan-out lines 402 are actually solid structures. The first data signal line 302 is arranged in the first display region 102, and an extension direction of the first data signal line 302 is parallel to the first direction. The first fan-out lines 402 are connected to the first data signal lines 302 in a one-to-one correspondence. The fan-out line is configured to transmit data signal output by a display driver chip to the data signal line. The first fan-out line 402 is partially disposed in the first display region 102 and partially disposed in the first fan-out region 202. In particular, n is a positive integer. For example, the display module may include 2160 data signal lines, of which 270 data signal lines may be noted as the first data signal lines 302, i.e., n=270. It can be understood that the proportion of the first data signal lines 302 to the total number of data signal lines in the display module may be set according to the shape of an outer contour of the display module or a width requirement of the lower bezel, which is not limited herein.

In the embodiments, by arranging a part of the fan-out line in the first display region 102, the length of the wiring in the first fan-out region 202 may be reduced, and in particular, the size of the fan-out region in the width direction of the display module may be reduced. Accordingly, the size of the fan-out region in the length direction of the display module (i.e., the width of the lower bezel) may be reduced proportionally, thereby ensuring the transmission speed of the data signals. In other words, the region of the first fan-out region 202 may be reduced without affecting the refresh rate of the display. The area of the fan-out region is a key factor in determining the width of the lower bezel of the display device. Therefore, by reducing the length of the wiring in the first fan-out region 202, the width of the lower bezel may be effectively reduced, thereby providing a display device with a narrow bezel.

Further, the fan-out region may include a bending region, and the first fan-out line 402 may be bent in the bending region to be connected to the display driver chip.

In some embodiments, the display module further includes multiple first pixel circuits. Referring to FIG. 2, FIG. 2 is a partial structural schematic view of a first pixel circuit according to some embodiments of the present disclosure. Each first pixel circuit is configured to connect a light-emitting device (not shown), for driving the connected light-emitting device to emit light. It can be understood that in the illustrated embodiments, the color of the light-emitting device corresponding to each first pixel circuit is for illustrative purposes only, and is not intended to limit the scope of the present disclosure. The multiple first pixel circuits in the display module are arranged in multiple columns, and the first direction is parallel to a column direction of the first pixel circuits. Each column includes multiple first pixel circuits. Moreover, the number of the first pixel circuits in each column may be the same or different, which can be set according to the actual shape of the display module. For example, when the display module is in the shape of an irregular screen such as a “notch” screen, the number of first pixel circuits in each column in the irregular region can be less than the number of first pixel circuits in other columns. Another example is that when an under-screen camera is required to be set up below the display module during mounting, the number of first pixel circuits in each column corresponding to the under-screen camera can be less than the number of first pixel circuits in other columns.

A gap exists between at least adjacent two columns of first pixel circuits, and a projection of first fan-out line 402 in the thickness direction of the display module is located in the gap. Specifically, the width of the gap is greater than a width threshold. The width threshold may be understood as a width that can ensure that the first fan-out line 402 will not affect the performance of the display module. The performance of the display module will not be affected, which includes that the optical performance will not be affected, that is, the first fan-out line 402 will not cause abnormal light emission problems in the display module; and further includes that the electrical performance will not be affected, that is, the electrical signals in the first fan-out line 402 will not interfere with the electrical signals in other lines. Therefore, in the embodiments, by providing a gap of an appropriate width in the adjacent first pixel circuits, the impact of the first fan-out line 402 on the display performance may be effectively reduced, thereby improving the display quality of the display module.

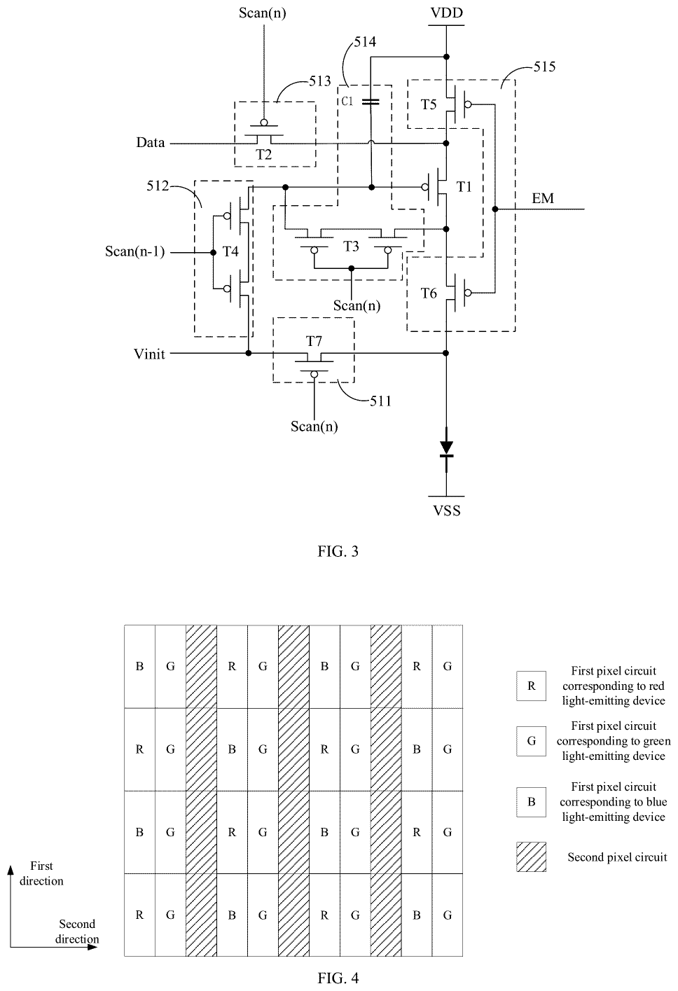

Referring to FIG. 3. FIG. 3 is a circuit diagram of a first pixel circuit according to some embodiments of the present disclosure. The embodiments provide a first pixel circuit of a 7T1C structure. Specifically, the first pixel circuit includes a driving transistor T1, an anode reset unit 511, a gate reset unit 512, a data writing unit 513, a threshold compensation unit 514, and a light emission control unit 515.

Specifically, the driving transistor T1 is configured to generate a driving current. The gate of the driving transistor T1 is connected to the gate reset unit 512, a first end of the driving transistor T1 is configured to receive a data signal Data, and a second end of the driving transistor T1 can output the driving current accordingly. The current value of the driving current is determined by the data signal Data transmitted by the first data signal line 302, and directly affects the brightness of the light-emitting device.

A control terminal of the anode reset unit 511 is configured to receive a second scanning signal Scan(n), an input terminal of the anode reset unit 511 is configured to receive a reset voltage signal Vinit, and an output terminal of the anode reset unit 511 is connected to the anode of the light-emitting device. The anode reset unit 511 is configured to reset the anode of the light-emitting device by receiving the reset voltage Vinit at the input after the gate of the driving transistor T1 is reset, and pulling down the anode of the light-emitting device connected thereto to the reset voltage Vinit. The reset voltage Vinit may be understood as a starting charging voltage of the anode of the light-emitting device. Resetting the anode of the light-emitting device can change the direction of the driving current configured to drive the light-emitting device, such that the driving current flows to the anode of the light-emitting device to drive the light-emitting device to emit light, and further, it will not affect the current value of the driving current, thereby ensuring the reliability of the brightness of the light-emitting device.

A control terminal of the gate reset unit 512 is connected to a gate control terminal to receive a first scanning signal Scan(n−1); an input terminal of the gate reset unit 512 is connected to a second reset terminal to receive the reset voltage Vinit; and an output terminal of the gate reset unit 512 is connected to the gate of the driving transistor T1. Specifically, the gate reset unit 512 can pull down the gate voltage of the driving transistor T1 to the reset voltage Vinit according to the first scan signal Scan(n−1) received at the control terminal to reset the gate of the driving transistor T1.

The data writing unit 513 includes a data writing transistor T2, the gate of the data writing transistor T2 being connected to the second scan signal line Scan(n), a first end of the data writing transistor T2 being connected to the data signal line, and a second end of the data writing transistor T2 being connected to the first end of the driving transistor T1. The data writing transistor T2 is configured to control the on and off of a signal transmission path between the second scan signal line and the first end of the driving transistor T1 according to the second scan signal Scan(n). Specifically, taking the data writing transistor T2 as a P-type transistor as an example, when the second scan signal Scan(n) is low, the data writing transistor T2 is turned on and transmits the data signal Data to the first end of the driving transistor T1; when the second scan signal Scan(n) is high, the data writing transistor T2 is turned off. It can be understood that the data writing unit 513 is not limited to the data writing transistor T2 of the present embodiments, and can be other circuit structures that can perform signal transmission functions according to an enable control signal.

The threshold compensation unit 514 is connected to the gate and the second end of the driving transistor T1, respectively, and is configured to control the on and off of a signal transmission path between the gate and the second end of the driving transistor T1 according to the second scan signal Scan(n). Specifically, by setting the threshold compensation unit 514, a threshold voltage of the driving transistor T1 can be compensated, thereby avoiding the threshold voltage of the driving transistor T1 from affecting the brightness of the light-emitting device.

The threshold compensation unit 514 includes a threshold compensation transistor T3 and a storage capacitor C1. The storage capacitor C1 is connected to a second power supply voltage terminal VDD and the gate of the driving transistor T1. The gate of the threshold compensation transistor T3 is connected to the first scan signal line, a first end of the threshold compensation transistor T3 is connected to the second end of the driving transistor T1, and a second end of the threshold compensation transistor T3 is connected to the gate of the driving transistor T1. The threshold compensation transistor T3 is configured to control the on and off of a signal transmission path between the gate and the second end of the driving transistor T1 according to the second scan signal Scan(n). Specifically, taking the threshold compensation transistor T3 as a P-type transistor as an example, when the second scan signal Scan(n) is low, threshold compensation is performed and the storage capacitor C1 is charged, thereby storing the compensation result in the storage capacitor C1.

In some embodiments, the threshold compensation transistor T3 may be a double-gate transistor. The threshold compensation transistor T3 having a double-gate transistor structure may effectively improve the reliability of the threshold compensation, thereby improving the display quality of the display device. It is understood that other transistors in the first pixel circuit may also be double-gate transistors to further improve the display quality.

The light emission control unit 515 includes a first control transistor T5 and a second control transistor T6. The gate of the first control transistor T5 is configured to receive a light emission control signal, a first end of the first control transistor T5 is connected to a second power supply voltage terminal, and a second end of the first control transistor T5 is connected to the first end of the driving transistor T1. The first control transistor T5 is configured to control the on and off of a signal transmission path between the second power supply voltage terminal and the first end of the driving transistor T1 according to a light control signal EM. The gate of the second control transistor T6 receives the light control signal EM, a first end of the second control transistor T6 is connected to the second end of the driving transistor T1, and a second end of the second control transistor T6 is connected to the anode of the light-emitting device. The second control transistor T6 is configured to control the on and off of a signal transmission path between the second end of the driving transistor T1 and the anode of the light-emitting device according to the light control signal EM. For example, both the first control transistor T5 and the second control transistor T6 are P-type transistors. When the light control signal EM is low, the first control transistor T5 and the second control transistor T6 are turned on, pulling up the voltage at the first end of the first driving transistor T1 to the second power supply voltage VDD, and the change in the gate-source voltage difference of the first driving transistor T1 generates the driving current, which is output to the light-emitting device, thereby controlling the light-emitting device to emit light.

It should be noted that the various transistors in the embodiments are not limited to the P-type transistors as above, but can be N-type transistors, etc. The corresponding driving method can also be adaptively adjusted according to the type of transistors. In addition, the first pixel circuit is not limited to the 7T1C structure, i.e., the first pixel circuit may have other numbers of transistors, so as to achieve a lightweight display device with a small number of transistors or more flexible display functions with a larger number of transistors. For example, other types of driving circuits such as 3T1C, 6T1C, and 6T2C may be adopted.

For example, all the thin-film transistors in the first pixel circuit may be low-temperature polycrystalline (LTPS) transistors. Another example is that at least one of the multiple thin-film transistors is an oxide transistor, i.e., the first pixel circuit is a low temperature polycrystalline silicon and oxide (LTPO) circuit. The transistor T3 and transistor T4 in FIG. 3 that affect leakage may be replaced with oxide thin-film transistors, which have better leakage suppression performance. That is, the circuit type in FIG. 3 may be changed from LTPS structure to LTPO structure, while keeping other transistors as low-temperature polycrystalline transistors, and the connection structure of the circuit remains unchanged, so as to achieve the purpose of controlling leakage.

Referring to FIG. 4, FIG. 4 is a partial structural schematic view of another first pixel circuit according to some embodiments of the present disclosure. In some embodiments, in the row direction, adjacent columns of the first pixel circuits form a first pixel array. The display module includes multiple first pixel arrays. Specifically, the embodiments in FIG. 4 show 4 first pixel arrays, each first pixel array including 8 first pixel circuits, and the 8 first pixel circuits arranged in 4 rows and 2 columns. Among them, any two adjacent columns of the first pixel circuits in the same first pixel array are closely arranged, that is, the distance between any two adjacent columns of the first pixel circuits is less than the width threshold.

Based on the structure of the first pixel arrays described above, a gap exists between two first pixel arrays adjacent in the row direction. In the embodiments, the display module further includes multiple second pixel arrays, each of the multiple second pixel arrays being disposed in a corresponding one of the multiple gaps. Each of the second pixel arrays includes multiple second pixel circuits arranged in columns. Specifically, the embodiments in FIG. 4 show three second pixel arrays, each of which includes four first pixel circuits arranged in four rows and one column.

The second pixel circuit may be understood as a dummy pixel. A dummy pixel circuit is a pixel circuit that is not connected to an actual light-emitting device. The dummy pixel circuit does not have a driving function and is only configured to occupy space to improve the uniformity of the distribution of pixel circuits. Combining and comparing the embodiments of FIGS. 2 and 4, it can be seen that no structure is provided in the gaps of the embodiments in FIG. 2, while a larger number of metal lines are provided at the first pixel circuits. It can be understood that the metal line has a certain reflective effect, while the gap does not have any reflective effect. Therefore, the reflective effect at different positions of the display module is not exactly the same, which accordingly causes the screen mura problem of the display module. Obviously, the gaps of the embodiments in FIG. 4 are arranged with second pixel circuits, such that the reflective effect at the gaps may be similar to the reflective effect of the first pixel circuits, thereby limiting the screen mura problem of the display module. In other words, in terms of screen mura, the display module of the embodiments in FIG. 4 has better performance than the display module of the embodiments in FIG. 2.

In some embodiments, the structure and size of the first pixel circuit and the second pixel circuit are the same. Specifically, by setting the second pixel circuit (dummy pixel) that is the same as the first pixel circuit, the structure, size, and spacing of each pixel circuit inside the display module can be ensured to be the same, thereby avoiding the screen mura problem caused by inconsistent circuit line density to the greatest extent. Moreover, the consistent structure of the pixel circuits is further conducive to the stability of the process, ensuring the electrical consistency of the thin-film transistors and the uniformity of the display. Furthermore, from the perspective of circuit design, adopting the arrangement method in the present embodiments can not only reduce the difficulty of designing the display module, but also reduce the impact of various optical effects on the dimensional structure during exposure preparation, thereby improving the yield of preparing the pixel circuit arrays.

Continuing with reference to FIG. 4, in some embodiments, the first pixel array includes 2 columns of the first pixel circuits, and the second pixel array includes 1 column of the second pixel circuits. In other embodiments, the first pixel array includes 4 columns of the first pixel circuits, and the second pixel array includes 1 column of the second pixel circuits. In yet other embodiments, the first pixel array includes 4 columns of the first pixel circuits, and the second pixel array includes 2 columns of the second pixel circuits. It can be understood that the structure of the first pixel array and the second pixel array can be determined together based on the size of the pixel circuit, the process level, the number of first fan-out lines to be set, etc.

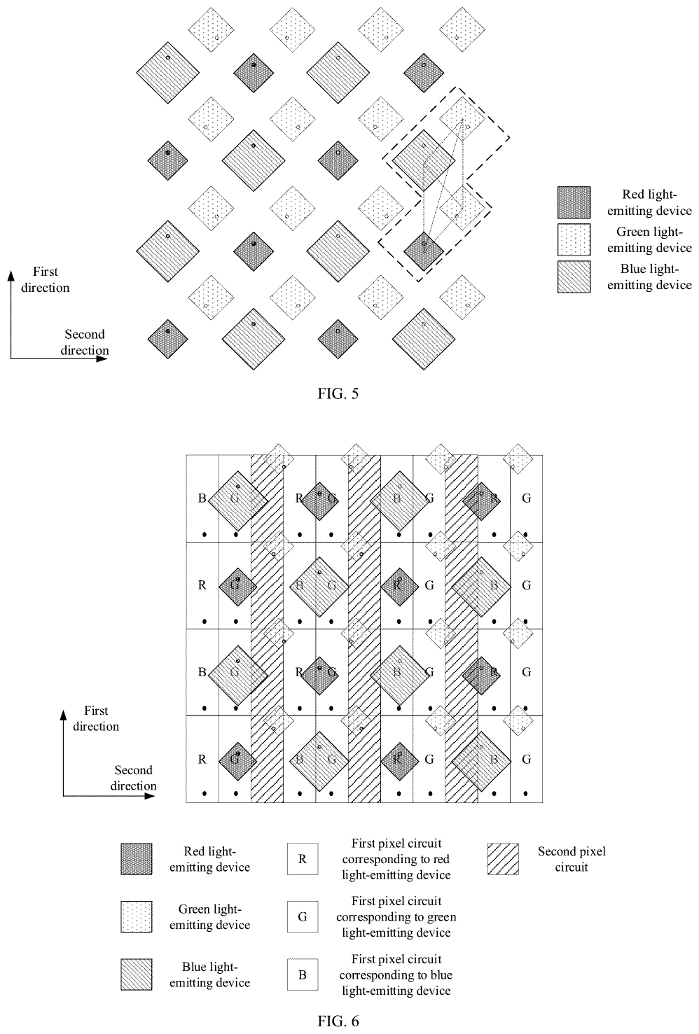

In some embodiments, the display module includes multiple light-emitting devices. FIG. 5 is a partial structural schematic view of an arrangement of light-emitting devices according to some embodiments of the present disclosure, and FIG. 6 is a partial structural schematic view of a display module formed by combining the pixel circuits in FIG. 4 with the light-emitting devices in FIG. 5. Referring to FIG. 5, in some embodiments, the multiple light-emitting devices in the display module are divided into multiple light-emitting repeat units. The structure in the dashed box in FIG. 5 corresponds to a smallest light-emitting repeat unit, and each of the light-emitting repeat units includes multiple light-emitting devices. The light-emitting repeat unit may include one red light-emitting device, two green light-emitting devices, and one blue light-emitting device. Two adjacent pixels may share a red light-emitting device or a blue light-emitting device, thereby improving the resolution of the display module and suppressing the color fringe problem of the display module, thereby improving the display quality.

In some embodiments, continuing with reference to FIG. 5, one of the green light-emitting devices and the red light-emitting devices in the light-emitting repeat unit have respectively centers disposed at two first vertices of a virtual quadrilateral, and the two first vertices are disposed on a diagonal line of the virtual quadrilateral. The other of the green light-emitting devices and the blue light-emitting device in the light-emitting repeat unit have respectively centers disposed at two second vertices of the virtual quadrilateral, and the two second vertices are disposed on the other diagonal line of the virtual quadrilateral.

It should be noted that the light-emitting devices in the embodiments may be, but are not limited to, organic light-emitting diodes (OLEDs), quantum dot light-emitting diodes (QLEDs), and micro light-emitting diodes (Micro LEDs). The embodiments of the present disclosure are illustrated taking an organic light-emitting diode as an example of a light-emitting device. Each light-emitting device may be an organic light-emitting diode of a different color, such as a red OLED, green OLED, and blue OLED. The driving circuit of each light-emitting device may be the same. However, the light-emitting layer materials of the light-emitting devices of different colors are different, thereby achieving display of different colors, such that the display device can achieve full-color display.

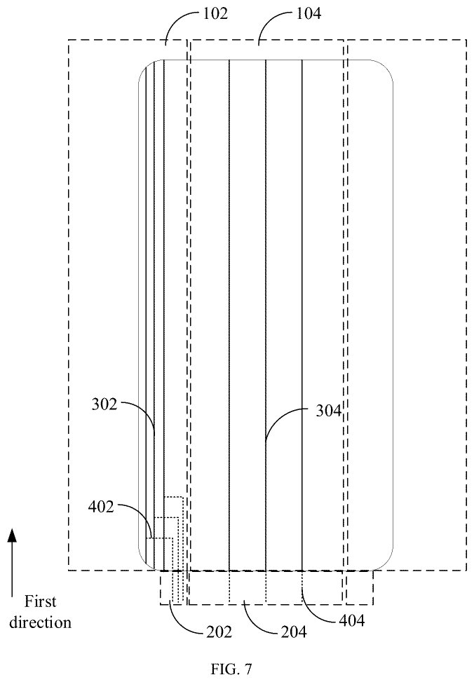

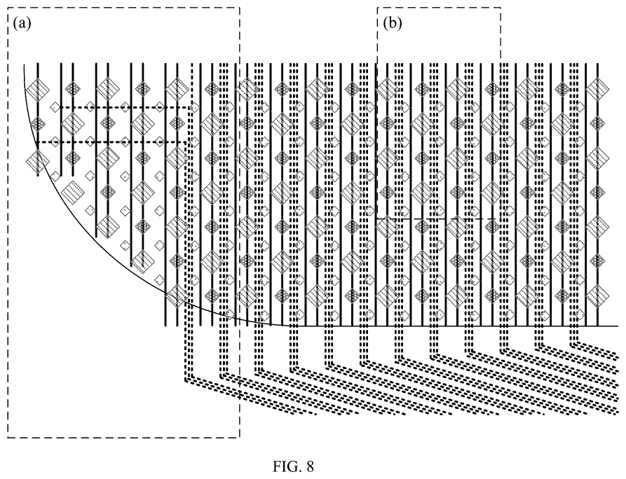

Referring to FIG. 7, FIG. 7 is a structural schematic view of another display module of according to some embodiments of the present disclosure. In some embodiments, the display module is arranged with two first display regions 102, and the display module is further arranged with a second display region 104. The two first display regions 102 are disposed on opposite sides of the second display region 104 in the row direction. It should be noted that in the embodiments of FIG. 7, there is a gap between the first display region 102 and the second display region 104 for the sake of clarity of the accompanying drawings. However, actually, the first display region 102 and the second display region 104 should be two regions arranged closely next to each other. It is understood that, in order to achieve a uniform display effect, the second display region 104 is arranged with first pixel circuits and second pixel circuits arranged in the same manner as those in the first display region 102, and also arranged with light-emitting devices arranged in the same manner as those in the first display region 102.

Further, continuing with reference to FIG. 7, in some embodiments, the display module further includes a second fan-out region 204, the second display region 104 and the second fan-out region 204 being arranged in sequence in the first direction, the second display region 104 being disposed adjacent to the first display region 102, and the second fan-out region 204 being disposed adjacent to the first fan-out region 202. The display module further includes m second data signal lines 304 and m second fan-out lines 404. The second data signal line 304 is arranged in the second display region 104 and extends in a direction parallel to the first direction. The m second fan-out lines 404 are connected to the m second data signal lines 304 in a one-to-one correspondence, and are arranged in the second fan-out region 204. Specifically, when the display module includes a total of 2160 data signal lines, of which 270 are the first data signal lines 302, then the remaining 1890 are the second data signal lines 304. In particular, the first fan-out lines 402 are each connected to a middle part of a corresponding first data signal line 302, and the second fan-out lines 404 are each connected to the end of a corresponding second data signal line 304.

In some embodiments, an overall outer contour of the second display region 104 and the two first display regions 102 have a rounded rectangular shape, the first display region 102 being a rounded region in the rounded rectangular shape, and the second display region 104 being a rectangular region in the rounded rectangular shape. It can be understood that, if the first fan-out line 402 is not designed, for fan-out wiring of the rounded corner region, an arc-shaped line is required to be applied to connect to the bending region, while the arc-shaped line is difficult to manufacture, which will affect the yield of preparation and even the display quality of the display module. Therefore, by virtue of the embodiments proposing the first fan-out line 402, for the rounded corner region, a straight-line wiring method can be adopted, thereby reducing the process difficulty of the fan-out line.

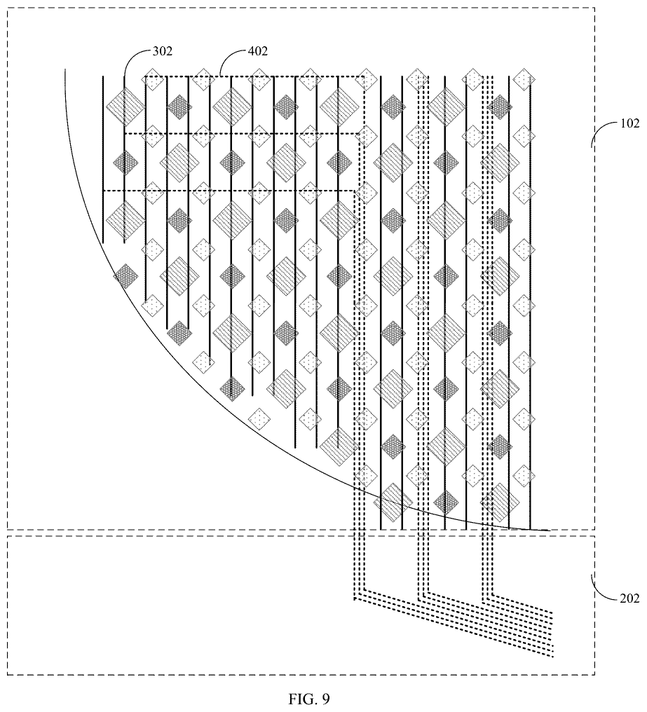

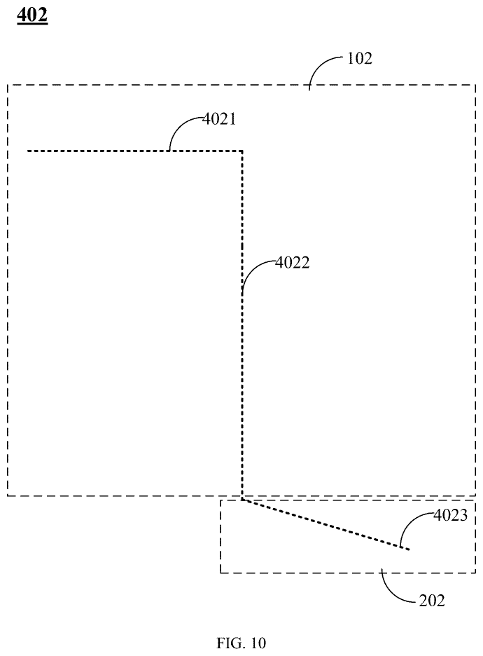

FIG. 8 is a local structural schematic view of a first display region and a first fan-out region according to some embodiments of the present disclosure, FIG. 9 is a local enlarged view of region (a) circumscribed in FIG. 8, and FIG. 10 is a structural schematic view of a first fan-out line. Specifically, referring to FIGS. 8 to 10, in some embodiments, the first fan-out line 402 includes a first line portion 4021 and a second line portion 4022 disposed in the first display region 102, an end of the first line portion 4021 being connected to the second line portion 4022, and the other end of the first line portion 4021 being connected to a corresponding first data signal line 302. In addition, the first fan-out line 402 further includes a third line portion 4023 arranged in the first fan-out region 202, and the third line portion 4023 is connected to an end of the second line portion 4022 away from the first line portion 4021. In some embodiments, an extension direction of the first line portion 4021 is parallel to the row direction, and an extension direction of the second line portion 4022 is parallel to the column direction. In the embodiments, by aligning the extension directions of the wiring with the row and column directions of the first pixel array, the design difficulty and process difficulty may be greatly reduced, and thus the preparation yield may be improved.

In some embodiments, a length of the first line portion 4021 connected to the first data signal line 302 near a boundary of the first display region 102 is greater than a length of the first line portion 4021 connected to the first data signal line 302 away from the boundary of the first display region 102. With the above arrangement, there is no crossing between different first fan-out lines 402, and therefore, there is no parasitic capacitance or signal interference between different first fan-out lines 402, thereby improving the stability and reliability of the signals transmitted by the first fan-out lines 402.

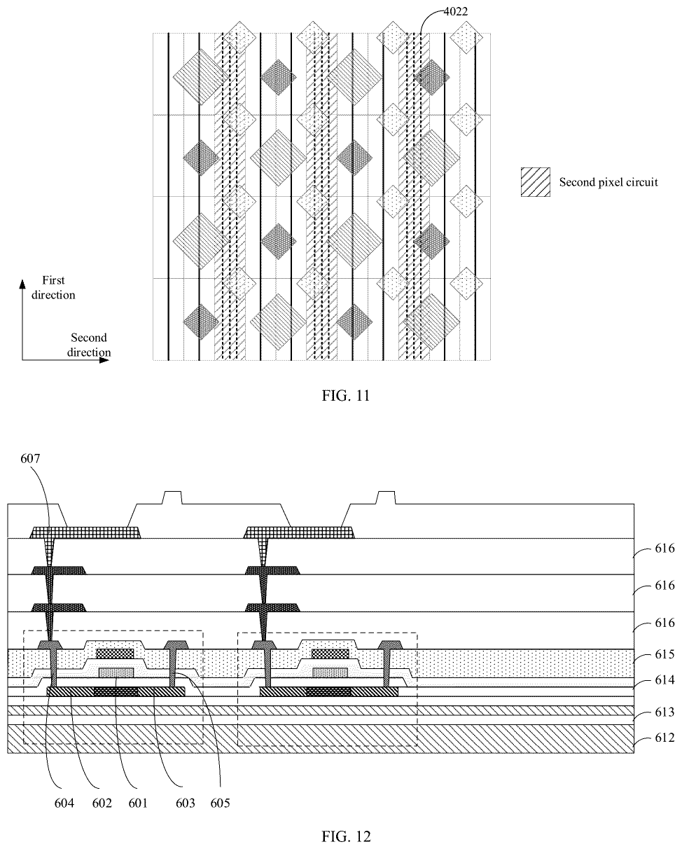

The embodiments provide a specific setting method for the first fan-out line 402, taking the second pixel circuit arranged in the gap as an example. It should be noted that in order to make FIGS. 8 and 9 clear, the schematic indication of the position of the first pixel circuit and the second pixel circuit is omitted. FIG. 11 is a local enlarged view of region (b) circumscribed in FIG. 8, and the relative positional relationship between the first fan-out line and the gap can be referred thereto. Referring to FIG. 11, a projection of the second line portion 4022 in the thickness direction of the display module is located in the gap, and specifically, when the second pixel circuit is arranged in the gap, the projection of the second line portion 4022 in the thickness direction of the display module is located in the second pixel circuit. It can be understood that when the second pixel circuit is a dummy pixel circuit, the second pixel circuit does not need to transmit a data signal, and accordingly, the second pixel circuit does not need to be connected to the first data signal line. That is, in the corresponding position for setting the first data signal lines connected to the first pixel circuits, it is not necessary to set any data signal line connected to the second pixel circuit, and the position corresponding to the second pixel circuit can be understood as a free position. Therefore, setting the first fan-out line in this position does not occupy additional space and further effectively improves the evenness of the signal line layout, thereby suppressing the screen mura problem.

Continuing with reference to FIG. 11, in some embodiments, the projections of the second line portions 4022 of multiple first fan-out lines in the thickness direction of the display module are located in the same gap, and the number of second line portions 4022 projected into each gap may be the same. In FIG. 11, the gaps are the regions arranged with the second pixel circuits. In the embodiments, the first fan-out line is not arranged in a central part of the display module. By arranging multiple second line portions 4022 in positions close to the boundary of the display module, the space occupied in the central part of the display module can be reduced. It can be understood that when a user views the display device, the display quality in the central part is required to be higher than that in the boundary. Therefore, the first fan-out lines are arranged in such a way as to effectively avoid affecting the display quality in the central part of the display module, thereby improving the viewing experience of the user.

In some embodiments, the number of the second line portions 4022 projected into each gap in the thickness direction of the display module is positively correlated with the number of the first pixel circuits in the first display region 102. Specifically, the greater the number of first pixel circuits in the first display region 102, the greater the number of first data signal lines required, and accordingly, the greater the number of first fan-out lines. Therefore, in order to reduce the space occupied in the central part of the display module, the arrangement density of the first fan-out lines at the boundary of the display module may be increased, thereby effectively avoiding the impact on the display quality in the central part of the display module, and thus improving the viewing experience of the user.

In some embodiments, the number of the second line portions 4022 projected into each gap in the thickness direction of the display module is 3. Specifically, the number of the second pixel arrays to be occupied can be obtained by a pre-set formula based on the number of second line portions 4022 projected into each gap, and the relationship between the number of columns in each first pixel array and the number of columns in each second pixel array. Among them, “being occupied” refers to that the second pixel array covers the projection of the second line portion 4022 of the first fan-out line 402. Conversely, the number of the second line portions 4022 projected into each gap can be determined by the number of second pixel arrays, that can be occupied, in the display module.

Referring to FIG. 12, FIG. 12 is a cross-sectional schematic view of a first pixel circuit according to some embodiments of the present disclosure. In some embodiments, the first pixel circuit is disposed on a substrate, and the substrate may include a polyimide (PI) base 612 and a first buffer layer 613 that are arranged in sequence and alternately. In the embodiments shown in FIG. 12, the substrate includes two PI bases 612 and two first buffer layers 613 that are arranged in sequence and alternately. It is understood that the substrate may further include a greater number of PI bases 612 and first buffer layers 613. The substrate is arranged with a first gate insulating layer 614, an interlayer insulating layer 615, and multiple planarization layers 616 for forming the first pixel circuit. Specifically, the first pixel circuit 60 includes multiple transistors, each transistor including a first gate 601, a first source 602, a first drain 603, a source contact structure 604, and a corresponding drain contact structure 605, and an anode layer 607 in a corresponding light-emitting device is electrically connected to the first source 602 via the source contact structure 604.

The embodiments of the present disclosure further provide a display device, including: the display module as described above. In the embodiments, a narrow-bezel display device based on the above-described display module is realized.

Any combination of the technical features of the above-described embodiments can be conducted. For the sake of conciseness in description, not all possible combinations of the technical features of the embodiments are described. However, as long as there is no conflict in the combination of these technical features, they should all be considered to be within the scope of the present disclosure.

The above-described embodiments only express several embodiments of the present disclosure. Although they are described in a relatively specific and detailed manner, they should not be construed as a limitation of the scope of the present disclosure. It should be noted that for those skilled in the art, a number of modifications and improvements can be made without departing from the concept of the embodiments of the present disclosure, and these all fall within the scope of the embodiments of the present disclosure. Therefore, the scope of the present disclosure shall be subject to the appended claims.

What is claimed is:

1. A display module, arranged with a first display region and a first fan-out region that are disposed in sequence in a first direction; wherein the first direction is perpendicular to a thickness direction of the display module; the display module comprises:
n first data signal lines, each arranged in the first display region; wherein an extension direction of each first data signal line is parallel to the first direction; and
n first fan-out lines, connected to the n first data signal lines in a one-to-one correspondence; wherein each first fan-out line is partially disposed in the first display region and partially disposed in the first fan-out region; n is a positive integer.

2. The display module according to claim 1, further comprising:
a plurality of first pixel circuits, arranged in a plurality of columns; wherein a gap exists between each of at least one pair of adjacent columns of the plurality of first pixel circuits, and a width of the gap is greater than a width threshold; the first direction is parallel to a column direction of the plurality of first pixel circuits;
wherein a projection of a corresponding first fan-out line in the thickness direction of the display module is located in the gap.

3. The display module according to claim 2, wherein in a row direction of the plurality of first pixel circuits, adjacent multiple columns of the plurality of first pixel circuits form a first pixel array; any two adjacent columns of the plurality of first pixel circuits in the first pixel array are arranged at a distance less than the width threshold;
wherein the display module comprises a plurality of the first pixel arrays; in the row direction, a gap exists between adjacent two of the plurality of first pixel arrays, and the display module further comprises:
a plurality of second pixel arrays; wherein each of the plurality of second pixel arrays is disposed in the gap between corresponding adjacent two of the plurality of first pixel arrays; each of the plurality of second pixel arrays comprises a plurality of second pixel circuits arranged in columns.

4. The display module according to claim 3, wherein each first pixel circuit has a same structure and size with each second pixel circuit.

5. The display module according to claim 3, wherein each first pixel array comprises two columns of the plurality of first pixel circuits, and each second pixel array comprises one column of the plurality of second pixel circuits.

6. The display module according to claim 3, wherein each first pixel array comprises four columns of the plurality of first pixel circuits, and each second pixel array comprises one column of the plurality of second pixel circuits.

7. The display module according to claim 3, wherein each first pixel array comprises four columns of the plurality of first pixel circuits, and each second pixel array comprises two columns of the plurality of second pixel circuits.

8. The display module according to claim 2, wherein the display module is arranged with two the first display regions and a second display region; the two first display regions are disposed on opposite sides of the second display region in a row direction.

9. The display module according to claim 8, wherein an overall outer contour of the second display region and the two first display regions have a rounded rectangular shape, each first display region being a rounded region in the rounded rectangular shape, and the second display region being a rectangular region in the rounded rectangular shape.

10. The display module according to claim 9, wherein each first fan-out line comprises a first line portion and a second line portion disposed in a corresponding first display region, an end of the first line portion being connected to the second line portion, and another end of the first line portion being connected to a corresponding first data signal line; a projection of the second line portion in the thickness direction of the display module is located in a corresponding gap.

11. The display module according to claim 10, wherein the projections of the second line portions of multiple of the n first fan-out lines in the thickness direction of the display module are located in a same corresponding gap; a number of the second line portions projected into each gap is the same.

12. The display module according to claim 11, wherein the number of the second line portions projected into each gap in the thickness direction of the display module is positively correlated with a number of the plurality of first pixel circuits in a corresponding first display region.

13. The display module according to claim 12, wherein the number of the second line portions projected into each gap in the thickness direction of the display module is 3.

14. The display module according to claim 10, wherein an extension direction of the first line portion is parallel to the row direction, and an extension direction of the second line portion is parallel to the column direction.

15. The display module according to claim 10, wherein a length of the first line portion of a corresponding first fan-out line connected to one of the n first data signal lines that is disposed near a boundary of a corresponding first display region is greater than a length of the first line portion of a corresponding first fan-out line connected to one of the n first data signal lines that is disposed away from the boundary of the corresponding first display region.

16. The display module according to claim 8, wherein the second display region is arranged with pixel circuits that are arranged in a same arrangement manner with the two first display regions; the display module comprises light-emitting devices that are arranged in a same arrangement manner in the two first display regions and the second display region.

17. The display module according to claim 16, wherein the light-emitting devices in the display module are divided into a plurality of light-emitting repeat units, and each of the plurality of light-emitting repeat units comprises one red light-emitting device, two green light-emitting devices, and one blue light-emitting device among the light-emitting devices.

18. The display module according to claim 17, wherein one of the two green light-emitting devices and the red light-emitting devices in each light-emitting repeat unit have respectively centers disposed at two first vertices of a corresponding virtual quadrilateral, and the two first vertices are disposed on a diagonal line of the corresponding virtual quadrilateral.

19. The display module according to claim 1, further comprising a second display region and a second fan-out region; wherein the second display region and the second fan-out region are arranged in sequence in the first direction, the second display region being disposed adjacent to the first display region, and the second fan-out region being disposed adjacent to the first fan-out region;
wherein the display module further comprises:
m second data signal lines, arranged in the second display region and extending in a direction parallel to the first direction; and
m second fan-out lines, connected to the m second data signal lines in a one-to-one correspondence, and arranged in the second fan-out region; m is a positive integer.

20. An electronic device, comprising a display module;
wherein the display module is arranged with a first display region and a first fan-out region that are disposed in sequence in a first direction; the first direction is perpendicular to a thickness direction of the display module; the display module comprises:
n first data signal lines, each arranged in the first display region; wherein an extension direction of each first data signal line is parallel to the first direction; and
n first fan-out lines, connected to the n first data signal lines in a one-to-one correspondence; wherein each first fan-out line is partially disposed in the first display region and partially disposed in the first fan-out region; n is a positive integer.
